(19) United States
(12) Patent Application Publication
(10) Pub. No.: US 2025/0246484 A1
(43) Pub. Date: Jul. 31, 2025

(54) MANUFACTURING METHOD OF SEMICONDUCTOR STRUCTURE

(71) Applicant: NANYA TECHNOLOGY CORPORATION, New Taipei city (TW)

(72) Inventor: Li Han LIN, New Taipei City (TW)

(21) Appl. No.: 18/427,897

(22) Filed: Jan. 31, 2024

(51) Int. Cl. H01L 21/768; H01L 23/528

(52) U.S. Cl. CPC H01L 21/76832; H01L 21/76831; H01L 23/528

(57) ABSTRACT

The present disclosure provides a manufacturing method of a semiconductor structure. A bit line structure and a trench adjacent to the bit line structure are provided, wherein a first spacer is disposed on a sidewall and a top surface of the bit line structure, and a second spacer is disposed on a sidewall and a top surface of the first spacer. A photoresist layer is formed in the trench, wherein the photoresist layer has a height that is smaller than a depth of the trench. A portion of the second spacer is removed, wherein the etched second spacer has a height that is substantially equal to the height of the photoresist layer. The photoresist layer is removed. A third spacer is formed on a sidewall of the etched second spacer, wherein the third spacer covers a top surface of the etched second spacer.

### BACKGROUND

### Field of Invention

The present invention relates to a manufacturing method of semiconductor structure. More particularly, the present invention relates to a bit-line spacer process.

### Description of Related Art

With high integration of the semiconductor device, the distance between conductive structures has decreased. For instance, as the critical dimension shrinks, a sacrificial layer is removed in the bit line contact process using an etchant with a relatively high etching rate. However, the spacer of the bit line structure may be removed when removing a sacrificial layer, potentially impacting the stability of the bit line structure.

Accordingly, how to provide a method of manufacturing semiconductor structure to solve the aforementioned problems becomes an important issue to be solved by those in the industry.

### SUMMARY

In accordance with an aspect of the present disclosure, a manufacturing method of a semiconductor structure is provided. A bit line structure and a trench adjacent to the bit line structure are provided, wherein a first spacer is disposed on a sidewall and a top surface of the bit line structure, and a second spacer is disposed on a sidewall and a top surface of the first spacer. A photoresist layer is formed in the trench, wherein the photoresist layer has a height that is smaller than a depth of the trench. A portion of the second spacer is removed to expose a top surface of the first spacer and forming an etched second spacer, wherein the etched second spacer has a height that is substantially equal to the height of the photoresist layer. The photoresist layer is removed to expose a bottom surface of the trench. A third spacer is formed on a sidewall of the etched second spacer, wherein the third spacer covers a top surface of the etched second spacer.

According to some embodiments of the present disclosure, wherein after forming the third spacer further includes forming a sacrificial layer in the trench, and the sacrificial layer is polished to expose the top surface of the bit line structure.

According to some embodiments of the present disclosure, wherein the sacrificial layer comprises oxide.

According to some embodiments of the present disclosure, wherein the sacrificial layer is polished by a chemical mechanical planarization process.

According to some embodiments of the present disclosure, wherein after exposing the top surface of the bit line structure further includes patterning the sacrificial layer to form a patterned sacrificial layer and an isolation trench, and a contact isolation layer is filled in the isolation trench.

According to some embodiments of the present disclosure, wherein the contact isolation layer comprises silicon nitride.

According to some embodiments of the present disclosure, wherein after filling the contact isolation layer further includes removing the patterned sacrificial layer to form a contact trench.

According to some embodiments of the present disclosure, wherein the sacrificial layer is removed by a wet etching process.

According to some embodiments of the present disclosure, wherein when removing the sacrificial layer, a portion of the first spacer and the third spacer is removed, and the second spacer is protected by the first spacer and the third spacer.

According to some embodiments of the present disclosure, wherein after removing the sacrificial layer further includes forming a cell contact in the contact trench, wherein the cell contact comprises polysilicon.

According to some embodiments of the present disclosure, wherein the first spacer and the third spacer comprise nitride.

In accordance with an aspect of the present disclosure, a manufacturing method of a semiconductor structure is provided. A bit line structure and a trench adjacent to the bit line structure are provided, wherein a first spacer is disposed on a sidewall and a top surface of the bit line structure, and a second spacer is disposed on a sidewall and a top surface of the first spacer. A photoresist layer is formed in the trench, wherein the photoresist layer comprises carbon and hydrogen. A portion of the second spacer is removed to expose a top surface of the first spacer and forming an etched second spacer, wherein a height of the etched second spacer is defined by the height of the photoresist layer. The photoresist layer is removed to expose a bottom surface of the trench. A third spacer is formed on a sidewall of the etched second spacer, wherein the third spacer covers a top surface of the etched second spacer.

According to some embodiments of the present disclosure, wherein the second spacer comprises oxide.

According to some embodiments of the present disclosure, wherein the photoresist layer comprises carbon and hydrogen.

According to some embodiments of the present disclosure, wherein the portion of the second spacer is removed by a wet etching process.

According to some embodiments of the present disclosure, wherein the photoresist layer is removed by a stripping process.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is a cross-sectional view schematic diagram of a semiconductor structure, in accordance with some embodiments;

FIG. 2 is a cross-sectional view schematic diagram of a semiconductor structure after forming a photoresist layer, in accordance with some embodiments;

FIG. 3 is a cross-sectional view schematic diagram of a semiconductor structure after removing a portion of the second spacer, in accordance with some embodiments;

FIG. 4 is a cross-sectional view schematic diagram of a semiconductor structure after removing the photoresist layer, in accordance with some embodiments;

FIG. 5 is a cross-sectional view schematic diagram of a semiconductor structure after forming a third spacer, in accordance with some embodiments;

FIG. 6 is a cross-sectional view schematic diagram of a semiconductor structure after forming a sacrificial layer, in accordance with some embodiments;

FIG. 7 is a top view schematic diagram of the semiconductor structure of FIG. 6, in accordance with some embodiments;

FIG. 8 is a top view schematic diagram of the semiconductor structure after patterning the sacrificial layer, in accordance with some embodiments;

FIG. 9 is a top view schematic diagram of the semiconductor structure after forming a contact isolation layer, in accordance with some embodiments;

FIG. 10 is a top view schematic diagram of the semiconductor structure after removing the patterned sacrificial layer, in accordance with some embodiments;

FIG. 11 is a cross-sectional view schematic diagram of the semiconductor structure of FIG. 6, in accordance with other embodiments;

FIG. 12 is a cross-sectional view schematic diagram of the semiconductor structure after forming cell contact in accordance with other embodiments.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

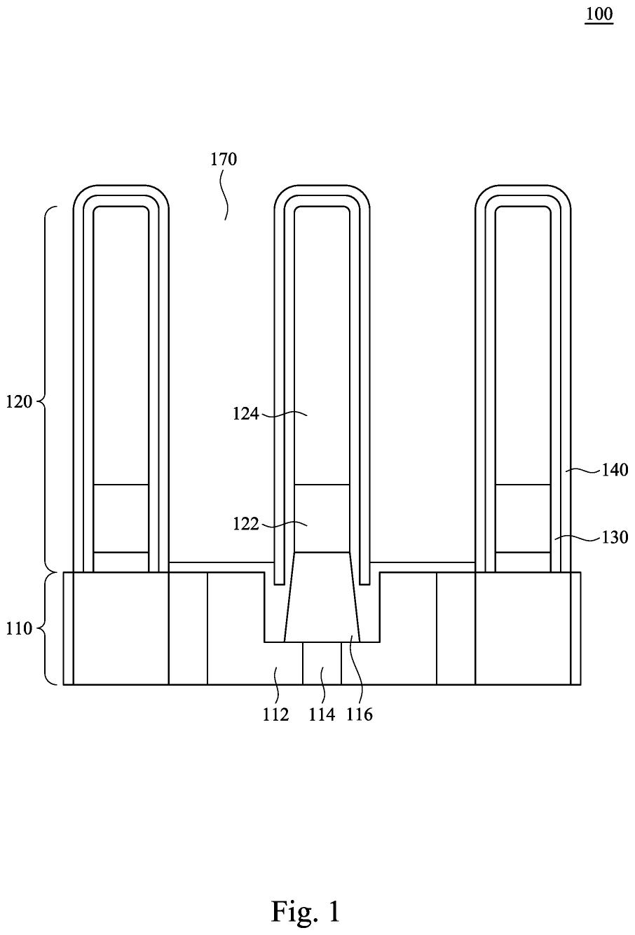

FIGS. 1-6 are cross-sectional views of various intermediate stages in the formation of a semiconductor structure 100, in accordance with some embodiments. The semiconductor structure 100 can be applied in an integrated circuit (IC) or a part thereof, such as a logic circuit, a resistor, a capacitor, an inductor, a memory (such as a dynamic random access memory (DRAM)), and the like. It should be understood that some elements of the semiconductor structure 100 are not shown in FIGS. 1-6 to simplify the drawings, and that additional elements may be included in other embodiments of the semiconductor structure 100.

Referring to FIG. 1, a bit line structure 120 is formed on a substrate 110. A trench T is formed adjacent the bit line structure 120. In some embodiments, the substrate 110 may be a semiconductor substrate, such as a bulk semiconductor substrate, a semiconductor-on-insulator (SOI) substrate, etc., wherein the insulator may be a buried oxide (BOX) layer, a silicon oxide layer, or the like. In some embodiments, the substrate 110 can be doped (eg, containing p-type or n-type dopants) or undoped. In some embodiments, the semiconductor material of the substrate 110 may include silicon, germanium, compound semiconductors (including silicon carbide, gallium arsenide, gallium phosphide, indium phosphide, indium arsenide, and/or indium antimonide), alloy semiconductors or a combination thereof. The substrate 110 can also be formed of other materials, such as sapphire, indium tin oxide, and the like. In some embodiments, the substrate 110 may include one or more active device (not shown) such as transistor.

The substrate 110 includes isolation areas 112, active areas 114, and direct contact 116. The active areas 114 are spaced apart by the isolation areas 112. The direct contact 116 contacts one of the active areas 114. The isolation areas 112 may be formed through shallow trench isolation (STI) process. The isolation areas 112 may include silicon oxide, silicon nitride, and silicon oxynitride. The isolation areas 112 may be a single layer including one kind of insulator, a double layer including two kinds of insulators, or a multilayer including a combination of at least three kinds of insulators. For example, the isolation areas 112 may include silicon oxide and silicon nitride. The direct contact 116 may include conductive material such as metal, metal alloy, metal nitride, or the like.

As shown in FIG. 1, the bit line structure 120 may include a conductive layer 122 and a hard mask layer 124 stacked on the conductive layer 122. In some embodiments, the conductive layer 122 includes conductive material such as metal, metal alloy, metal nitride, or the like. In some examples, the conductive layer 122 may include tungsten. In some embodiments, the hard mask layer 124 may include silicon oxide, silicon nitride, other dielectric materials or combinations thereof. The bit line structure 120 may be formed by suitable deposition and patterning process. The conductive layer 122 may be electrically connected to the direct contact 116.

As shown in FIG. 1, a first spacer 130 is disposed on a sidewall and a top surface of the bit line structure 120. A second spacer 140 is disposed on a sidewall and a top surface of the first spacer 130. The first spacer 130 may include nitride. The second spacer 140 may include oxide. In some embodiments, the first spacer 130 and the second spacer 140 may include different materials.

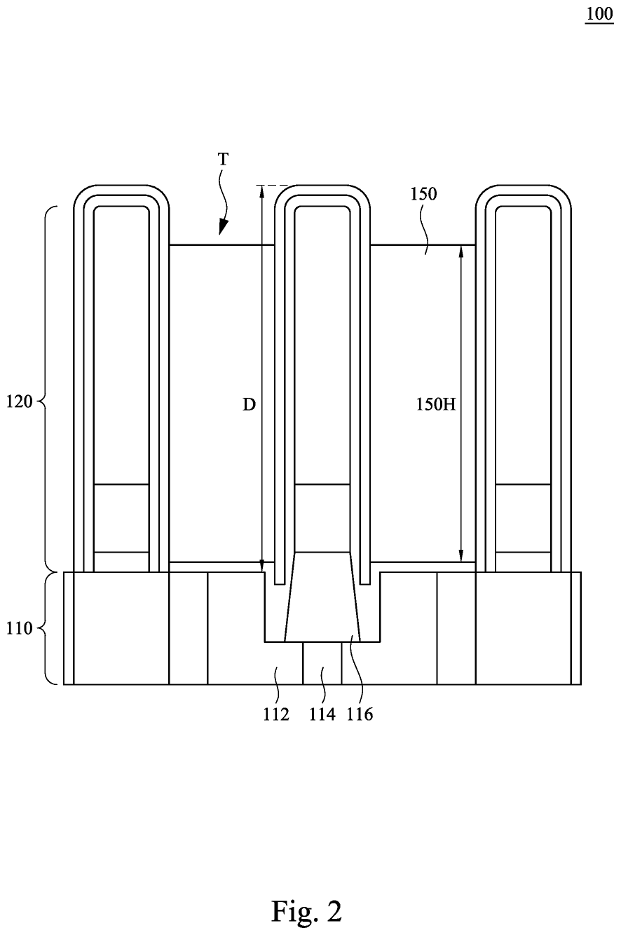

Referring to FIG. 2, a photoresist layer 150 is formed in the trench T, wherein the photoresist layer 150 has a height 150H that is smaller than a depth D of the trench T. In some embodiments, the photoresist layer 150 may include carbon and hydrogen. In some embodiments, the photoresist layer 150 may be formed by any suitable deposition process such as chemical vapor deposition (CVD), atomic layer deposition (ALD), or physical vapor deposition (PVD).

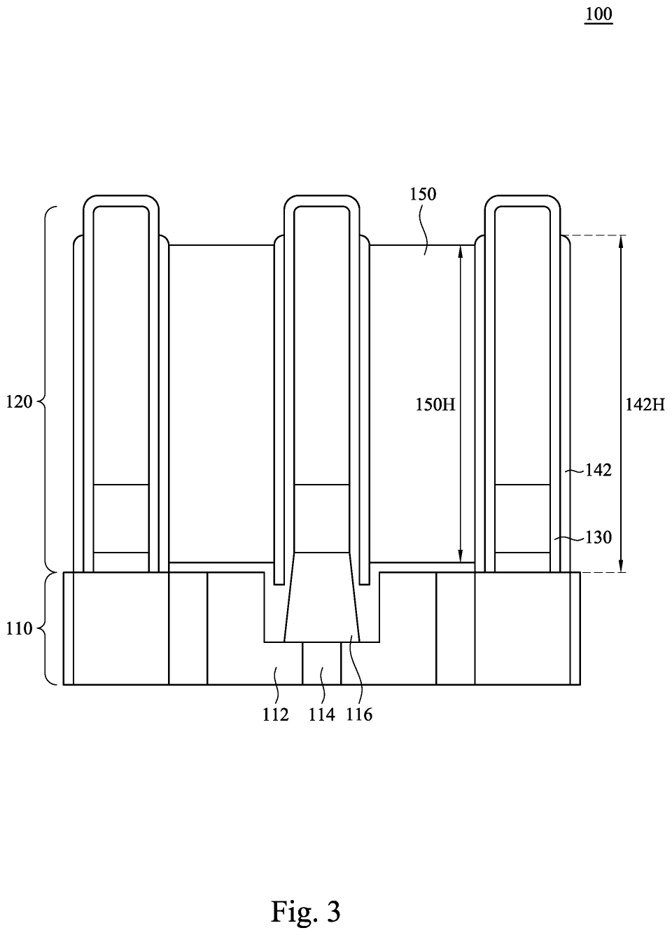

Referring to FIG. 3, a portion of the second spacer 140 is removed to expose a top surface of the first spacer 130, and an etched second spacer 142 is formed. In some embodiments, the second spacer 140 is removed using a suitable etching process, such as wet etching process. The wet etching process may use suitable etchants, such as acidic etchant. In some embodiments, the etched second spacer 142 has a height 142H is substantially equal to the height 150H of the photoresist layer 150. In other words, the height 142H of the etched second spacer 142 is defined by the height 150H of the photoresist layer 150. For example, according to the etchant used in the subsequent etching process, the height 150H of the photoresist layer can be modified to further adjust the height 142H of the second spacer 142.

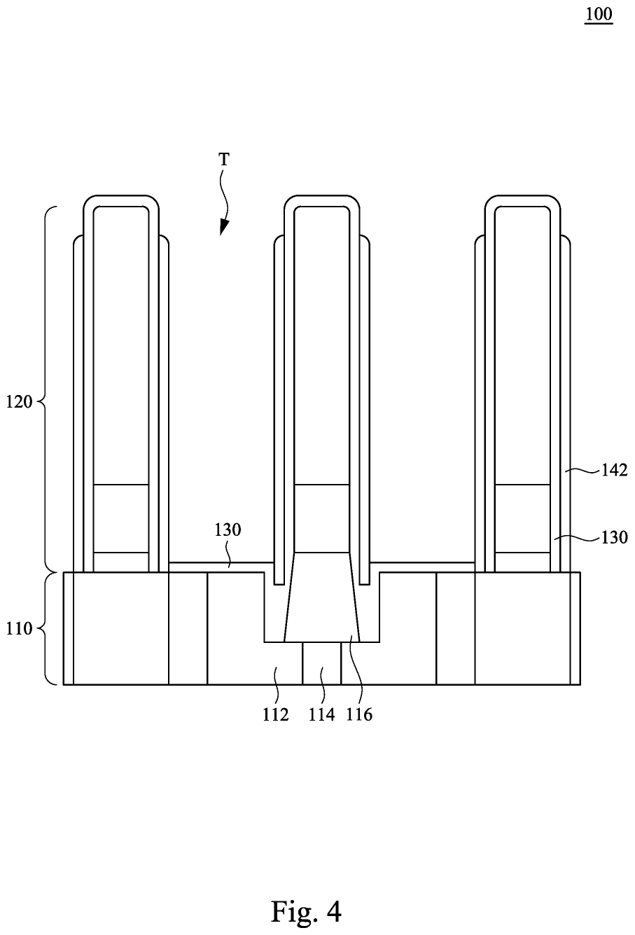

Referring to FIG. 4, the photoresist layer 150 is removed to expose a bottom surface of the trench T. In some embodiments, the photoresist layer 150 is removed using a suitable stripping process. In some embodiments, a portion of the first spacer 130 may be disposed on the bottom surface of the trench.

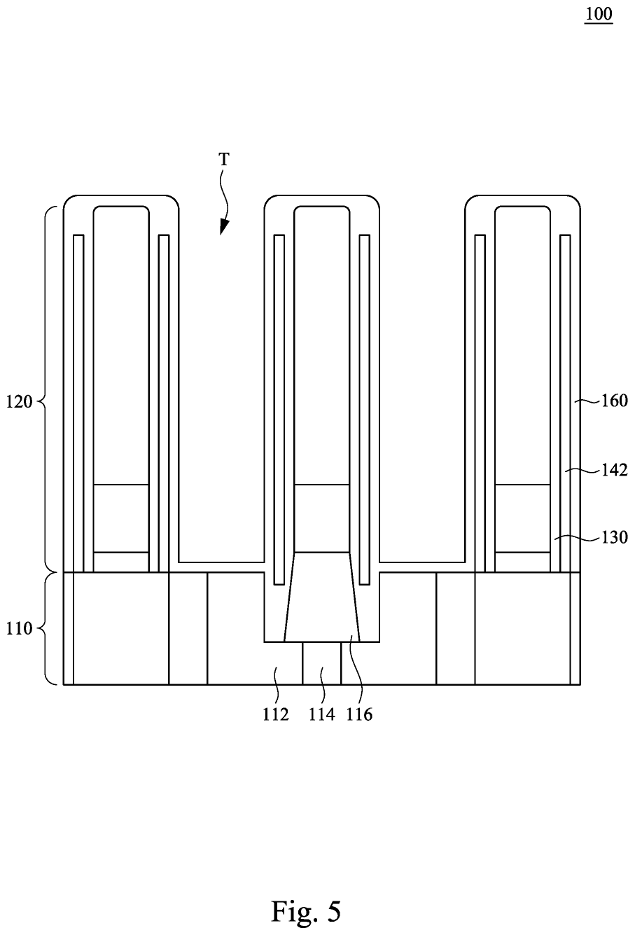

Referring to FIG. 5, a third spacer 160 is formed on a sidewall of the etched second spacer 142, wherein the third spacer 160 covers a top surface of the etched second spacer 142. In some embodiments, the third spacer 160 may be formed by any suitable deposition process such as chemical vapor deposition (CVD), atomic layer deposition (ALD), or physical vapor deposition (PVD). In some embodiments, the material of the third spacer 160 is exactly the same as the material of the second spacer 140 (etched second spacer 142). In some embodiments, the first spacer 130 and the third spacer 160 may include nitride. The portion of the third spacer 160 that covers the top surface of the etched second spacer 142 serves as a buffer layer to protect the etched second spacer 142 from subsequent etching processes.

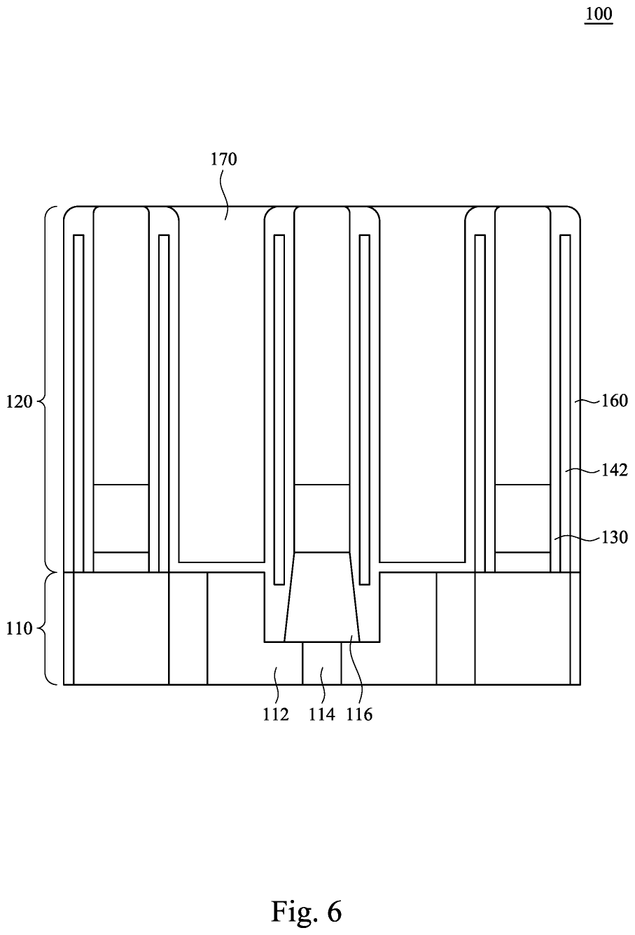

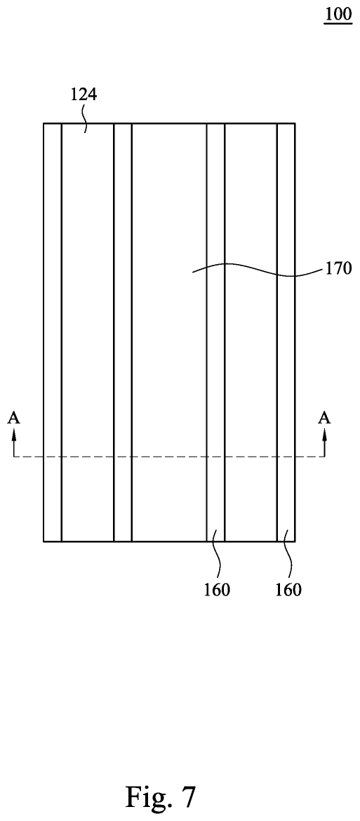

Next, referring to FIG. 6 and FIG. 7. FIGS. 7-10 are top view schematic diagrams of various intermediate stages in the formation of the semiconductor structure 100, in accordance with some embodiments. FIG. 6 and FIG. 7 are at the same intermediate stage in the formation of the semiconductor structure 100. FIG. 7 is a top view of FIG. 6, and FIG. 6 is based on a reference cross-sectional view taken along line A-A shown in FIG. 7.

As shown in FIG. 6 and FIG. 7, a sacrificial layer 170 is formed in the trench T. In some embodiments, the sacrificial layer 170 may be formed by any suitable deposition process such as chemical vapor deposition (CVD), atomic layer deposition (ALD), or physical vapor deposition (PVD). In some embodiments, the sacrificial layer 170 may include oxide. Subsequently, the sacrificial layer 170 is polished, and the top surface of the bit line structure 120 is exposed. More specifically, the top surface of the hard mask layer 124 is exposed. For example, polishing the sacrificial layer 170 is performed by chemical mechanical planarization (CMP) process.

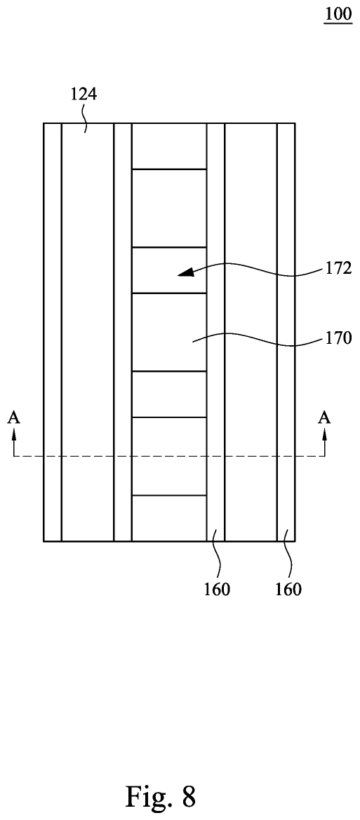

Referring to FIG. 8, the sacrificial layer 170 is patterned to form an isolation trench 172. The sacrificial layer 170 may be patterned by a mask (not shown). The sacrificial layer 170 may be patterned by suitable photolithography process and suitable removing process. In some embodiments, a portion of the sacrificial layer 170 is removed using a suitable etching process, such as wet etching process. The wet etching process may use suitable etchants, such as acidic etchant.

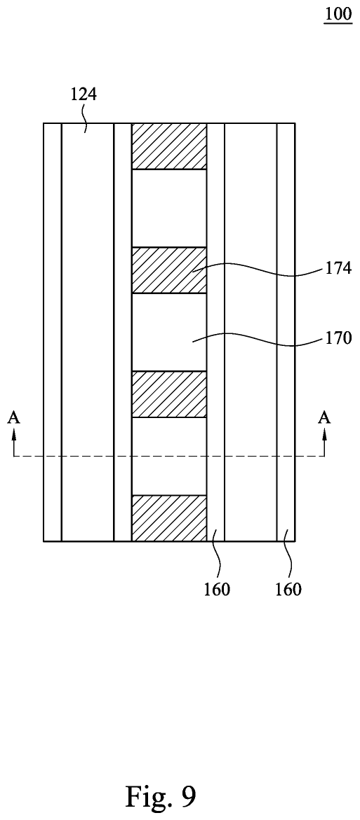

Referring to FIG. 9, a contact isolation layer 174 is filled in the isolation trench 172. In some embodiments, the contact isolation layer 174 may be formed by any suitable deposition process such as chemical vapor deposition (CVD), atomic layer deposition (ALD), or physical vapor deposition (PVD). In some embodiments, the contact isolation layer 174 includes silicon nitride.

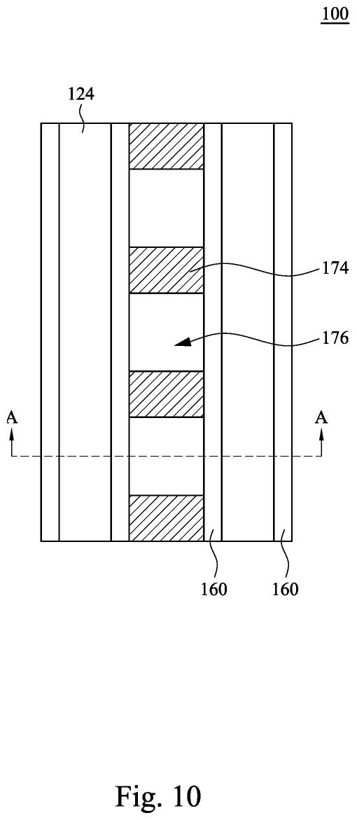

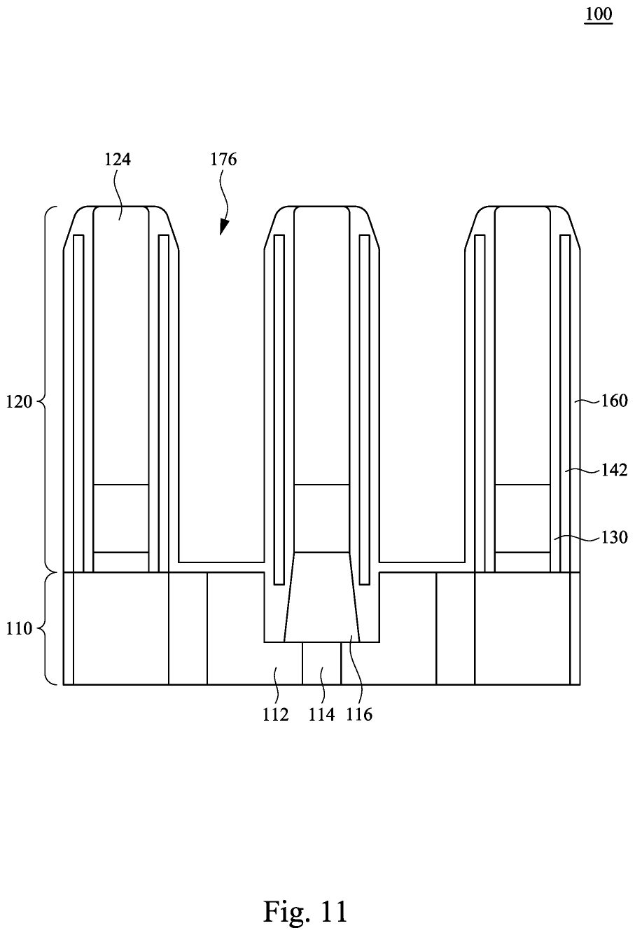

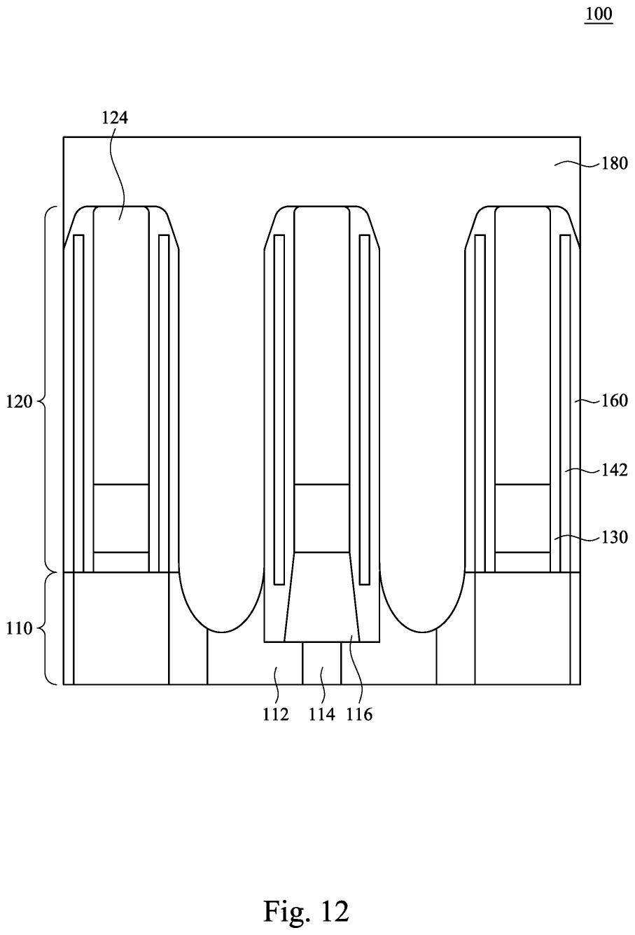

Next, referring to FIG. 10 and FIG. 11. FIGS. 11-12 are top view schematic diagrams of various intermediate stages in the formation of the semiconductor structure 100, in accordance with other embodiments. FIG. 10 and FIG. 11 are at the same intermediate stage in the formation of the semiconductor structure 100. FIG. 10 is a top view of FIG. 11, and FIG. 11 is based on a reference cross-sectional view taken along line A-A shown in FIG. 10.

As shown in FIG. 10, the sacrificial layer 170 is removed to form a contact trench 176. In some embodiments, the sacrificial layer 170 is removed using a suitable etching process, such as wet etching process. The wet etching process may use suitable etchants, such as acidic etchant. As shown in FIG. 11, even if the sacrificial layer 170 is removed using an etchant with a relative high etching rate, the etched second spacer 142 is still protected by the first spacer 130 and the third spacer 160. In other words, the etched second spacer 142 can be covered by first spacer 130 and the third spacer 160.

Referring to FIG. 12, a cell contact 180 is formed in the contact trench 176. In some embodiments, the cell contact 180 may include suitable silicon-containing material. For example, the cell contact 180 may include polysilicon. An etching process may be performed to expose a portion of isolation areas 112 of the substrate 110 and a portion of active areas 114 of the substrate 110. In some embodiments, the cell contact 180 may be formed by any suitable deposition process such as chemical vapor deposition (CVD), atomic layer deposition (ALD), or physical vapor deposition (PVD). The cell contact 180 may fill the exposed isolation areas 112 and the exposed active areas 114.

In the manufacturing of the present disclosure, before forming the third spacer, a photoresist layer is first formed and the top portion of the second spacer is removed. In other words, the height of the second spacer is defined by the height of the photoresist layer. Next, a third spacer is formed, and the second spacer is completely covered by the first spacer and the third spacer. In the subsequent etching process, the first spacer and the third spacer can protect the second spacer. Even if an etchant with a higher etching rate is used in the subsequent etching process, the second spacer may not be exposed. By using the manufacturing method of the present disclosure, the stability of the bit line structure may be improved.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A manufacturing method of a semiconductor structure, comprising:
providing a bit line structure and a trench adjacent to the bit line structure, wherein a first spacer is disposed on a sidewall and a top surface of the bit line structure, and a second spacer is disposed on a sidewall and a top surface of the first spacer;
forming a photoresist layer in the trench, wherein the photoresist layer has a height that is smaller than a depth of the trench;
removing a portion of the second spacer to expose a top surface of the first spacer and forming an etched second spacer, wherein the etched second spacer has a height that is substantially equal to the height of the photoresist layer;
removing the photoresist layer to expose a bottom surface of the trench;
forming a third spacer on a sidewall of the etched second spacer, wherein the third spacer covers a top surface of the etched second spacer.

2. The manufacturing method of a semiconductor structure of claim 1, wherein after forming the third spacer further comprises:
forming a sacrificial layer in the trench; and
polishing the sacrificial layer and exposing the top surface of the bit line structure.

3. The manufacturing method of a semiconductor structure of claim 2, wherein the sacrificial layer comprises oxide.

4. The manufacturing method of a semiconductor structure of claim 2, wherein the sacrificial layer is polished by a chemical mechanical planarization process.

5. The manufacturing method of a semiconductor structure of claim 2, wherein after exposing the top surface of the bit line structure further comprises:
patterning the sacrificial layer to form a patterned sacrificial layer and an isolation trench; and
filling a contact isolation layer in the isolation trench.

6. The manufacturing method of a semiconductor structure of claim 5, wherein the contact isolation layer comprises silicon nitride.

7. The manufacturing method of a semiconductor structure of claim 5, wherein after filling the contact isolation layer further comprises:
removing the patterned sacrificial layer to form a contact trench.

8. The manufacturing method of a semiconductor structure of claim 7, wherein the sacrificial layer is removed by a wet etching process.

9. The manufacturing method of a semiconductor structure of claim 7, wherein when removing the sacrificial layer, a portion of the first spacer and the third spacer is removed, and the second spacer is protected by the first spacer and the third spacer.

10. The manufacturing method of a semiconductor structure of claim 7, wherein after removing the sacrificial layer further comprises:
forming a cell contact in the contact trench, wherein the cell contact comprises polysilicon.

11. A manufacturing method of a semiconductor structure, comprising:
providing a bit line structure and a trench adjacent to the bit line structure, wherein a first spacer is disposed on a sidewall and a top surface of the bit line structure, and a second spacer is disposed on a sidewall and a top surface of the first spacer;
forming a photoresist layer in the trench, wherein the photoresist layer comprises carbon and hydrogen;
removing a portion of the second spacer to expose a top surface of the first spacer and forming an etched second spacer, wherein a height of the etched second spacer is defined by the height of the photoresist layer;
removing the photoresist layer to expose a bottom surface of the trench;
forming a third spacer on a sidewall of the etched second spacer, wherein the third spacer covers a top surface of the etched second spacer.

12. The manufacturing method of a semiconductor structure of claim 11, wherein the first spacer and the third spacer comprise nitride.

13. The manufacturing method of a semiconductor structure of claim 11, wherein the second spacer comprises oxide.

14. The manufacturing method of a semiconductor structure of claim 11, wherein the portion of the second spacer is removed by a wet etching process.

15. The manufacturing method of a semiconductor structure of claim 11, wherein the photoresist layer is removed by a stripping process.
